(19) United States
(12) Patent Application Publication
(10) Pub. No.: US 2026/0280730 A1
(43) Pub. Date: Sep. 17, 2026

(54) DIAGNOSTIC METHOD FOR A RADIO BROADCAST RECEIVING SYSTEM AND THE RADIO BROADCAST RECEIVING SYSTEM

(71) Applicant: MERCEDES-BENZ GROUP AG, Stuttgart (DE)

(72) Inventor: Dominik GAMMERT, Neulingen (DE)

(21) Appl. No.: 19/166,994

(22) PCT Filed: Mar. 4, 2024
(86) PCT No.: PCT/EP2024/055609

§ 371 Date: Sep. 19, 2025

(30) Foreign Application Priority Data
Mar. 20, 2023 (DE) 10 2023 001 094.4

(51) Int. Cl. H04B 17/29

(52) U.S. Cl. CPC H04B 17/295

(57) ABSTRACT

A radio broadcast receiving system of a motor vehicle with two transmission/reception paths is subject to diagnostics using locally-generated test signals.

### BACKGROUND AND SUMMARY OF THE INVENTION

Exemplary embodiments of the invention relate to a diagnostic method for a radio broadcast receiving system of a motor vehicle, as well as to the radio broadcast receiving system and the motor vehicle with the radio broadcast receiving system.

EP 0 816 859 B1 discloses a radio broadcast receiving system for a motor vehicle having two receivers and two antennas. The receivers and the antennas define two transmission/reception paths, such that the radio broadcast receiving system can be operated in a phase diversity mode. The radio broadcast receiving system furthermore has a controller for controlling the two transmission/reception paths. The controller and the two receivers are combined into a so-called remote tuner module, and the antennas are installed in a window of the motor vehicle.

A diagnostic method for the antennas of a radio broadcast receiving system is also known in EP 0 816 859 B1. Here, a test signal is generated by means of an external signal generator and received by the respective antenna. The received test signal is then evaluated, wherein the signal strength of the test signal here provides information about the function of the respective antenna.

The disadvantage here is that an additional signal generator is necessary, which hampers and complicates the radio broadcast receiving system and the implementation of the diagnostic method.

DE 200 19 677 U1 discloses an antenna system with several antennas connectable in predetermined combinations to at least two receivers via a combination unit. The antenna system additionally has a signal processing unit for evaluating the output signals of the receivers and a control unit for performing a self-test. At least one of the antennas transmits test signals at a test frequency predetermined via a first receiver, said test signals being coupled into at least one further antenna. To perform the self-test, the reception levels of the second receiver are recorded as actual values and compared to predetermined target values.

DE 103 38 825 A1 discloses a diagnostic device and a diagnostic method for a multi-antenna system, by means of which a defect in individual antennas of the multi-antenna system can be detected. For this purpose, a device is formed to record the length of the switch-on time and/or information about signal strength and signal quality of each of the antennas of the multi-antenna system. A reference value is determined from this recorded data by an analysis device. Furthermore, by means of a comparison with predetermined, prestored reference values, the analysis device determines a defect in individual antennas as present when the reference value is below the predetermined reference value when all antennas are fully functional.

Exemplary embodiments of the invention are thus directed to an improved or at least alternative embodiment for a diagnostic method of the generic type, in which the described disadvantages are overcome, as well as to a corresponding radio broadcast receiving system and a motor vehicle with the radio broadcast receiving system.

The present invention is based on the general idea of using a local oscillator installed into the receiver to generate a test signal and thus avoiding the use of an external signal generator.

The diagnostic method according to the invention is designed for a radio broadcast receiving system of a motor vehicle. Here, the radio broadcast receiving system has a first transmission/reception path and a second transmission/reception path. The first transmission/reception path is formed by a first receiver and a first antenna that transmits signals or is electrically connected to the first receiver, and the second transmission/reception path is formed by a second receiver and a second antenna that transmits signals or is electrically connected to the second receiver. Here, the two antennas can be coupled to each other for signal transmission or electromagnetically. In addition, the radio broadcast receiving system has a controller for controlling the two transmission/reception paths. According to the invention, a diagnosis is performed in the diagnostic method. In the first transmission/reception path, a test signal with a predetermined test frequency is generated here via a local oscillator of the first receiver and transmitted via the first antenna. In the second transmission/reception path, the transmitted test signal is received via the second antenna and forwarded to the controller via the second receiver. Here, it is understood that the second receiver is set to receive the test signal at the predetermined test frequency. The controller then evaluates the functionality of the second antenna based on the received test signal.

In the diagnostic method according to the invention, the local oscillator of the first receiver is used to generate the test signal at the predetermined test frequency. Thus, an external signal generator is not necessary to perform the diagnostic method, and thus the number of components and the effort required to diagnose the second antenna is reduced. This also reduces costs, and the radio broadcast receiving system is more reliable due to fewer components.

The test signal generated in the first transmission/reception path can be received by other radio broadcast receiving systems within a certain radius and thus interfere with the other radio broadcast receiving systems. In order to avoid this, the diagnostic method can be carried out, in particular, in a controlled environment.

In the diagnostic method according to the invention, the test signal is generated using the local oscillator of the first receiver. Signals generated by a local oscillator typically have high quality and high amplitude stability and can be particularly suitable as test signals. Current radio broadcast receiving systems typically operate at an intermediate frequency in the range of several hundred kHz, and the respective receivers are constructed as so-called low-IF receivers (low-IF: low-intermediate-frequency). Here, the local oscillator can largely cover the frequency range and be used to generate the mixed frequency for the test signal.

In addition to the local oscillator, the first receiver can also have further components. Thus, in addition to the local oscillator, the first receiver can have at least one bandpass filter and/or at least one mixer and/or at least one analog-to-digital converter and/or at least one digital signal processor. It is understood that the first receiver and the second receiver can be constructed identically to each other. In particular, the second receiver can have identical components.

The first antenna and the second antenna can be coupled to each other for signal transmission or electromagnetically, and can be arranged or aligned at a suitable distance and in a suitable position in relation to each other. The first antenna and the second antenna can be window antennas or can be formed by antenna structures for the windows of the motor vehicle, as described in more detail below.

The controller can control the two transmission/reception paths and evaluate the received test signal or assess the functionality of the second antenna by means of the received test signal. The controller can be implemented, for example, by a microcontroller. The two receivers and the controller can be installed or integrated in a common unit—a so-called tuner IC (IC: integrated circuit) or a so-called remote tuner module. The two receivers and the controller can be installed, in particular, close to the antenna—i.e., in particular in the same vehicle.

The two transmission/reception paths are fully functional and independent of each other. The radio broadcast receiving system can thus be operated in a phase diversity mode. In the phase diversity mode, the transmission/reception path with lower interference is used. It is understood that the radio broadcast receiving system is only operated in the phase diversity mode outside the diagnostic method.

After being received by the second receiver, the received test signal can be processed and stored in the controller. In particular, the amplitude or field strength of the received test signal at the predetermined test frequency can here be stored and used to evaluate the functionality of the second antenna. The evaluation of the functionality of the second antenna by the controller is described in more detail below.

During diagnosis, the test signal can be routed from the local oscillator of the first receiver to the first antenna via a bypass path with a switch. Here, the switch of the bypass path can be closed while performing the diagnosis and open otherwise. The switch can, in particular, be a HF (high frequency) switch. Via the bypass path and the closed switch, the test signal can be routed from the local oscillator of the first receiver to the first antenna and transmitted there. Here, the switch is closed exclusively during diagnosis, such that signals from the local oscillator of the first receiver cannot negatively affect the operation of the radio broadcast receiving system outside of diagnosis. In other words, the first antenna remains decoupled from the local oscillator of the first receiver outside diagnosis, and interference between the two receivers can be prevented.

According to the invention, a reference measurement is performed prior to the diagnosis in the diagnostic method. Since it cannot be ruled out that the second antenna receives further external signals during the diagnostic method, these further external signals can be recorded in the reference measurement and taken into consideration when evaluating the functionality of the second antenna. In other words, a zero measurement can be performed, which can subsequently be taken into consideration when evaluating the functionality of the second antenna. Here, during the reference measurement, the first receiver in the first transmission/reception path is switched off. In the second transmission/reception path, a surroundings signal at the predetermined test frequency is then received via the second antenna and transmitted to the controller via the second receiver. It is understood that the respective test signal and the respective surroundings signal have the same test frequency. The controller then stores the received surroundings signal for evaluating the functionality of the second antenna. Here, in particular, the amplitude or the field strength of the received surroundings signal at the predetermined test frequency can be measured and stored.

The controller can then compare the received test signal and the received surroundings signal at the respective predetermined test frequency. Here, as soon as the test signal is stronger than the surroundings signal by a predefined reference value at the respective predetermined test frequency, the controller can evaluate the second antenna as functional or otherwise as non-functional. Here, in particular, the amplitude or field strength of the test signal and the amplitude or field strength of the surroundings signal at the respective predetermined test frequency can be compared to each other. The aforementioned predetermined reference values can be pre-stored values which have been measured in a preliminary measurement on a functional second antenna. These reference values can be stored in the radio broadcast receiving system, for example at the factory before commissioning of the radio broadcast receiving system in the controller.

During diagnosis, several test signals, each with a deviating test frequency, can be generated and used by the controller to evaluate the functionality of the second antenna. In other words, a predetermined frequency range can be discretely sampled during diagnosis. Thus, the functionality of the second antenna can be tested in the predetermined frequency range. Similarly, during the reference measurement, several surroundings signals, each with a deviating test frequency, can be generated and stored by the controller to evaluate the functionality of the second antenna. Here, the test signals and the surroundings signals are respectively generated at the same test frequency. By means of the controller, the test frequency of the test signal of the local oscillator of the first receiver can be freely adjusted, such that the signal strength of the received test signal can be compared to the signal strength of the surroundings signal at the predefined test frequency.

A phase diversity mode of the radio broadcast receiving system can be switched off before the diagnosis and/or before the reference measurement and switched on after the diagnosis and/or after the reference measurement. The first receiver and/or the second receiver of the radio broadcast receiving system can be muted before the diagnosis and/or before the reference measurement and unmuted-i.e., the mute function is lifted-after the diagnosis and/or after the reference measurement.

The invention also relates to a radio broadcast receiving system for a motor vehicle. Here, the radio broadcast receiving system has a first transmission/reception path and a second transmission/reception path. The first transmission/reception path is formed by a first receiver with a local oscillator and a first antenna that transmits signals or is electrically connected to the first receiver, and the second transmission/reception path is formed by a second receiver and a second antenna that transmits signals or is electrically connected to the second receiver. Here, the two antennas can be coupled to each other in a signal-transmitting or electromagnetically manner. In addition, the radio broadcast receiving system has a controller for controlling the two transmission/reception paths. According to the invention, the radio broadcast receiving system is designed to carry out the diagnostic method described above.

The second transmission/reception path can have a signal amplifier, and the signal amplifier can be switched between the second antenna and the second receiver. The signal amplifier can, in particular, amplify the test signal received by the second antenna and/or the surroundings signal received by the second antenna. The first transmission/reception path can have a redirection path with a switch, wherein the redirection path leads from the local oscillator of the first receiver to the first antenna. As already described above, the switch can, in particular, be an HF switch.

As already described above, the controller of the radio broadcast receiving system can be implemented by a microcontroller. The controller can be expediently connected to the receivers in a signal-transmitting or electrically connected manner. The first receiver can also comprise further components in addition to the local oscillator.

Thus, in addition to the local oscillator, the first receiver can have at least one bandpass filter and/or at least one mixer and/or at least one analog-to-digital converter and/or at least one digital signal processor. It is understood that the second receiver and the first receiver can be constructed identically to each other. In particular, the second receiver can have identical components.

In order to avoid repetitions, in relation to further features of the radio broadcast receiving system, reference is made to the above description of the diagnostic method.

The invention also relates to a motor vehicle with the radio broadcast receiving system described above. As already described above, the radio broadcast receiving system has the first antenna and the second antenna. According to the invention, the antennas of the radio broadcast receiving system are window antennas. Here, the motor vehicle can have at least one window, and the first antenna and the second antenna can be installed in the same window. Alternatively, the motor vehicle can have at least two physically separate windows, and the first antenna is installed in one window and the second antenna in the other window.

Further important features and advantages of the invention emerge from the sub-claims, from the drawings and from the corresponding description of the figures by means of the drawings.

It is understood that the features mentioned above and still to be explained below can be used not only in the respectively specified combination, but also in other combinations or on their own, without leaving the scope of the present invention.

Preferred exemplary embodiments of the invention are depicted in the drawings and are explained in more detail in the description below, wherein the same reference numerals relate to the same or similar or functionally identical components.

### BRIEF DESCRIPTION OF THE DRAWING FIGURES

Shown are, schematically in each case:

FIG. 1 a view of a radio broadcast receiving system according to the invention on a window of a motor vehicle;

FIG. 2 a flowchart relating to a diagnostic method according to the invention in the radio broadcast receiving system according to the invention.

### DETAILED DESCRIPTION

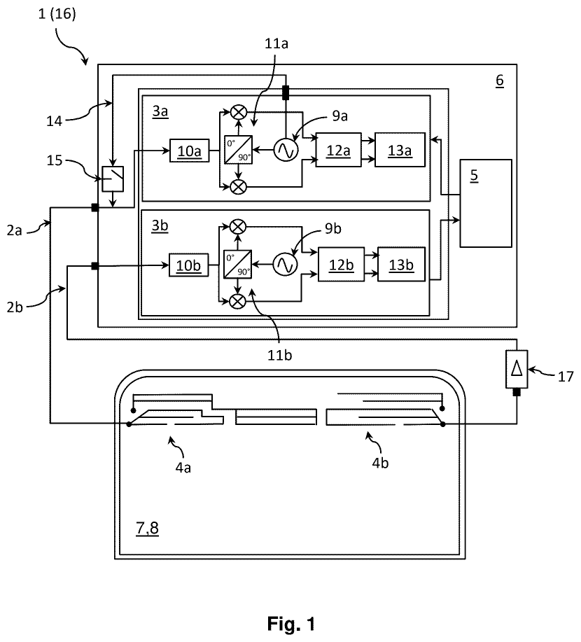

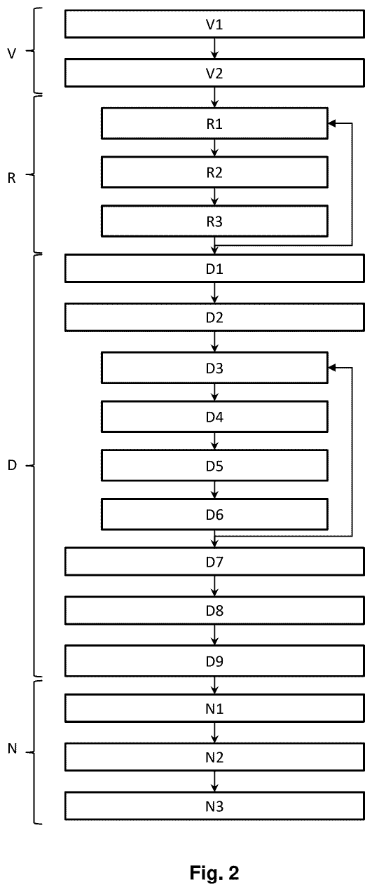

FIG. 1 shows a view of a radio broadcast receiving system 1 according to the invention. The radio broadcast receiving system 1 is designed to carry out a diagnostic method 16 according to the invention. The diagnostic method 16 and the function of the radio broadcast receiving system 1 are explained in more detail below with reference to FIG. 2.

Here, the radio broadcast receiving system 1 has a first transmission/reception path 2a and a second transmission/reception path 2b. The radio broadcast receiving system 1 additionally comprises a first receiver 3a and a first antenna 4a, which are connected to each other for signal transmission or electrically conductively and form the transmission/reception path 2a. In addition, the radio broadcast receiving system 1 comprises a second receiver 3b and a second antenna 4b, which are connected to each other for signal transmission or electrically conductively and form the transmission/reception path 2b. The first antenna 4a and the second antenna 4b can be coupled to each other for signal transmission or electromagnetically and are correspondingly arranged in relation to each other.

In addition, the radio broadcast receiving system 1 has a controller 5 for controlling the two transmission/reception paths 2a and 2b. The controller 5 and the two receivers 3a and 3b are combined in a common unit 6-a so-called tuner IC or a so-called remote tuner module.

The two antennas 4a and 4b are window antennas or are formed by flat antenna structures and are installed on a common window 7 of a motor vehicle 8. Here, the window 7 is not part of the radio broadcast receiving system 1 according to the invention.

The respective receiver 3a or 3b respectively comprises a local oscillator 9a or 9b, a bandpass filter 10a or 10b, a mixer 11a or 11b, an analog-to-digital converter 12a or 12b, and a digital signal processor 13a or 13b. The two receivers 3a and 3b are constructed identically to each other. The respective receiver 3a or 3b is connected to the controller 5 via the digital signal processor 13a or 13b for signal transmission or electrical connection.

The first transmission/reception path 2a additionally comprises a redirection path 14 with a switch 15. Here, the redirection path 14 leads from the local oscillator 9a of the first receiver 3a to the first antenna 4a. The second transmission/reception path 2b additionally comprises a signal amplifier 17, which is arranged or switched between the second antenna 4b and the second receiver 3b and amplifies received signals of the second antenna 4b.

FIG. 2 shows a flowchart of the diagnostic method 16 according to the invention in the radio broadcast receiving system 1 according to the invention. In the diagnostic method 16 according to the invention, the functionality of the second antenna 4b can be checked. Here, a preparation V with substeps V1-V2, a reference measurement R with substeps R1-R3, a diagnosis D with substeps D1-D9, and a postprocessing N with substeps N1-N3 are performed.

During the preparation V, the radio broadcast receiving system 1 is prepared for further steps. Here, in the substep V1, the second receiver 3b of the radio broadcast receiving system 1 is muted. Subsequently, in the substep V2, a phase diversity mode of the radio broadcast receiving system 1 is switched off.

Since it cannot be ruled out that the second antenna 4b receives further external signals during the diagnostic procedure 16, the reference measurement R is performed. During the reference measurement R, surroundings signals or external signals are measured and taken into consideration when evaluating the functionality of the second antenna 4b. Here, in the substep R1, the second receiver 3b is set to a predetermined first test frequency. Subsequently, in the substep R2, the surroundings signal at the predetermined first test frequency is received via the second antenna 4b, and in the substep R3, the received surroundings signal is transmitted via the second receiver 3b to the controller 5 and stored there. The substeps R1-R3 are performed for several test frequencies deviating from one another. In other words, surroundings signals in a predetermined frequency range are recorded and stored in the controller 5. Here, in particular, the amplitude or the field strength of the received surroundings signal can be stored in an allocated memory cell of the respective predetermined test frequency.

As soon as the reference measurement R is completed, the diagnosis D is carried out. During the diagnosis D, the second antenna 4b is tested for functionality. In the substep D1, the local oscillator 9a of the first receiver 3a is activated, and in the substep D2, the switch 15 is closed, and thus the bypass path 14 is activated. In the substep D3, a test signal with the predetermined first test frequency is generated in the first transmission/reception path 2a via the local oscillator 9a and transmitted by the first antenna 4a. In the substep D4, the second receiver 3b is set to the predetermined first test frequency. Subsequently, in the substep D5, the test signal transmitted by the first antenna 4a at the predetermined first test frequency is received via the second antenna 4b and, in the substep D6, is transmitted via the second receiver 3b to the controller 5 and stored there. Here, too, the amplitude or field strength of the received test signal can be stored in an allocated memory cell of the respective predetermined test frequency. Here, the substeps D3-D6 are performed for several test frequencies deviating from one another. Here, too, a frequency range is measured discretely. The predetermined test frequencies of the generated test signals correlate with the test frequencies used in the reference measurement R, such that a comparison of the surroundings signals and the test signals is possible. In the substep D7, the switch 15 is opened and the bypass path 14 is deactivated. Subsequently, the local oscillator 9a of the first receiver 3a is deactivated in the substep D8.

In the substep D9, the evaluation of the functionality of the second antenna 4b is carried out. For this purpose, the received surroundings signal and the received test signal are compared for the respective predetermined test frequency. As already described above, the stored amplitudes or field strengths can be compared to one another here. If the test signal is stronger than the surroundings signal by a predefined reference value at the predetermined test frequencies, the second antenna 4b is functional; otherwise, it is not functional. Here, the predefined reference values can be stored in the controller 5 and ascertained, for example, by means of a preliminary measurement on a further functional antenna. This can be done at the factory before commissioning of the radio broadcast receiving system 1.

After the diagnosis D, the postprocessing N of the radio broadcast receiving system 1 now takes place. In the substep N1, the original reception frequency is set in the receivers 3a and 3b. In the substep N2, the phase diversity mode of the radio broadcast receiving system 1 is switched on. Subsequently, in the substep N3, the second receiver 3b of the radio broadcast receiving system 1 is unmuted or the mute function of the second receiver 3b is lifted.

Although the invention has been illustrated and described in detail by way of preferred embodiments, the invention is not limited by the examples disclosed, and other variations can be derived from these by the person skilled in the art without leaving the scope of the invention. It is therefore clear that there is a plurality of possible variations. It is also clear that embodiments stated by way of example are only really examples that are not to be seen as limiting the scope, application possibilities or configuration of the invention in any way. In fact, the preceding description and the description of the figures enable the person skilled in the art to implement the exemplary embodiments in concrete manner, wherein, with the knowledge of the disclosed inventive concept, the person skilled in the art is able to undertake various changes, for example, with regard to the functioning or arrangement of individual elements stated in an exemplary embodiment without leaving the scope of the invention, which is defined by the claims and their legal equivalents, such as further explanations in the description.

1-9. (canceled)

10. A diagnostic method for a radio broadcast receiving system of a motor vehicle, the diagnostic method comprising:
performing a reference measurement by
switching off a first receiver in a first transmission/reception path of the radio broadcast receiving system, wherein the first transmission/reception path comprises the first receiver with a first local oscillator and a first antenna connected to the first receiver for signal transmission;
receiving, via a second antenna in a second transmission/reception path of the radio broadcast receiving system, a surroundings signal of a predetermined test frequency, wherein the second transmission/reception path comprises the second receiver and the second antenna connected to a second receiver for signal transmission, and wherein the first and second antennas are couplable to each other to transmit signals;
passing, by the second receiver to a controller of the radio broadcast receiving system, the received surroundings signal; and
storing, by the controller, the received surroundings signal; and
performing a diagnosis of the radio broadcast receiving system by
generating, by the first local oscillator, a test signal with the predetermined test frequency;
transmitting, via the first antenna, the test signal;
receiving, via the second antenna and the second receiver, the transmitted test signal;
passing, by the second receiver to the controller, the received test signal; and
evaluating, by the controller based on the received test signal and the stored received surroundings signal, functionality of the second antenna.

11. The diagnostic method of claim 10, wherein the test signal is passed from the first local oscillator of the first receiver to the first antenna via a bypass path with a switch, and the switch of the bypass path is closed when performing the diagnosis and is open when not performing the diagnosis.

12. The diagnostic method of claim 10, wherein
the controller evaluates the received test signal and the received surroundings signal at the respective predetermined test frequency, and
as soon as the received test signal is stronger than the received surroundings signal by a predefined reference value at the respective predetermined test frequency, the controller evaluates the second antenna as functional and otherwise evaluates the second antenna as non-functional.

13. The diagnostic method of claim 10, wherein
during the diagnosis, several test signals, each with a test frequency deviating from one another, are generated and used by the controller to evaluate the functionality of the second antenna, or
during the reference measurement, several surroundings signals, each with a test frequency deviating from one another, are received and stored by the controller for further evaluation of the functionality of the second antenna.

14. The diagnostic method of claim 10, wherein
a phase diversity mode of the radio broadcast receiving system is switched off before the diagnosis or before the reference measurement and the phase diversity mode is switched on after the diagnosis or after the reference measurement, or
before the diagnosis or before the reference measurement, the first receiver or the second receiver is muted and after the diagnosis or after the reference measurement the first or second receiver is unmuted.

15. A radio broadcast receiving system for a motor vehicle, the radio broadcast receiving system comprising:
a first transmission/reception path comprising a first receiver with a first local oscillator and a first antenna connected to the first receiver for signal transmission;
a second transmission/reception path with a second receiver and a second antenna connected to the second receiver for signal transmission, wherein the first and second antennas are couplable to each other to transmit signals; and
a controller configured to control the first and second transmission/reception paths,
wherein in a reference measurement
the controller is configured to switch off the first receiver;
the second antenna is configured to receive a surroundings signal of a predetermined test frequency;
the second receiver is configured to pass the received surroundings signal to the controller; and
the controller is configured to store the received surroundings signal; and
wherein in a diagnosis of the radio broadcast receiving system
the first local oscillator is configured to generate a test signal with the predetermined test frequency;
the first antenna is configured to transmit the test signal;
the second antenna and the second receiver are configured to receive the transmitted test signal;
passing, the second receiver is configured to pass the received test signal to the controller; and
the controller is configured to evaluate, based on the received test signal and the stored received surroundings signal, functionality of the second antenna.

16. The radio broadcast receiving system of claim 15, wherein the second transmission/reception path has a signal amplifier, and the signal amplifier is switchable between the second antenna and the second receiver.

17. The radio broadcast receiving system of claim 15, wherein the first transmission/reception path has a bypass path with a switch, and the bypass path leads from the first local oscillator of the first receiver to the first antenna.

18. A motor vehicle comprising:
at least one window; and
a radio broadcast receiving system comprising
a first transmission/reception path comprising a first receiver with a first local oscillator and a first antenna connected to the first receiver for signal transmission;
a second transmission/reception path with a second receiver and a second antenna connected to the second receiver for signal transmission, wherein the first and second antennas are couplable to each other to transmit signals; and
a controller configured to control the first and second transmission/reception paths,
wherein in a reference measurement
the controller is configured to switch off the first receiver;
the second antenna is configured to receive a surroundings signal of a predetermined test frequency;
the second receiver is configured to pass the received surroundings signal to the controller; and
the controller is configured to store the received surroundings signal; and
wherein in a diagnosis of the radio broadcast receiving system
the first local oscillator is configured to generate a test signal with the predetermined test frequency;
the first antenna is configured to transmit the test signal;
the second antenna and the second receiver are configured to receive the transmitted test signal;
passing, the second receiver is configured to pass the received test signal to the controller; and
the controller is configured to evaluate, based on the received test signal and the stored received surroundings signal, functionality of the second antenna,
wherein the first and second antennas are window antennas, and
wherein the first and second antennas are installed on a same one of the at least one window or the first and second antennas are installed on different ones of the at least one window.
